(19) United States
(12) Patent Application Publication
(10) Pub. No.: US 2011/0222288 A1
(43) Pub. Date: Sep. 15, 2011

(54) LIGHTING DEVICE

(75) Inventors: Michel C. J. M. Vissenberg, Eindhoven (NL); Maarten M. J. W. Van Herpen, Eindhoven (NL); Marcellinus P. C. M. Krijn, Eindhoven (NL); Oscar H. Willemsen, Eindhoven (NL); Ramon P. Van Gorkom, Eindhoven (NL); Tim Dekker, Eindhoven (NL)

(73) Assignee: KONINKLIJKE PHILIPS ELECTRONICS N.V., EINDHOVEN (NL)

(21) Appl. No.: 13/129,902

(22) PCT Filed: Nov. 12, 2009
(86) PCT No.: PCT/IB09/55022

§ 371 Date: May 18, 2011

(30) Foreign Application Priority Data
Nov. 20, 2008 (EP) 08169534.8

(51) Int. Cl. F21V 33/00; H01L 33/00; F21V 29/00

(52) U.S. Cl. 362/253; 257/80; 257/E33.076

(57) ABSTRACT

There is disclosed a lighting device of which the light sources and/or optical elements are hidden in a first cover state associated with a first light state. This enables an unobtrusive lighting system in the first cover state. In a second cover state associated with a second light state, optical elements, e.g. shutters or beam shaping elements, are switched, induced by the heat or the light flux generated by the light sources, such that the lighting system can function properly.

### FIELD OF THE INVENTION

The invention relates to the field of light systems, more specifically to a lighting device comprising a light emitting diode and a cover element. The invention also relates to a method for the same.

### BACKGROUND OF THE INVENTION

There is an increasing need to integrate lighting in interiors as unobtrusively as possible. This may enable architects and interior designers to create an interior style that clearly distinguishes one building from another.

Lighting devices which are suitable for such environments typically comprise a light source and a light attenuation device. Such lighting devices have traditionally utilized external control signals to operate the light attenuation device. The light attenuation device, which typically is a mechanical shutter is thus placed in the path of light between the light source and the aperture of the housing of the lighting device in order to either block the passage of light from the lamp through the aperture or permit the passage of light there through.

U.S. Pat. No. 4,513,358 discloses a light system with switchable shutters wherein the shutters are switched depending on resistive heating or direct heat of a light bulb. The system comprises a light emitting element in form of a light bulb and a cover in form of louvers. The louvers are controlled by an actuator which is heated either by resistive heating or by direct heat of the light bulb when the lamp is activated. When heated, the actuator serves to pivot the louvers into an open position. Once the lamp is deactivated, heating of the actuator is terminated, and the louvers are automatically closed to protect the lens by a spring as the actuator cools.

U.S. Pat. No. 4,513,358 thus discloses a light system wherein infrared heating is utilized in order to make an actuator switch louvers from a closed state to an open state.

There is also a need for lighting devices which do not disturb the visual appearance of the spaces in which the lighting devices are to be arranged in.

There is thus a need for an improved unobtrusive lighting device.

### SUMMARY OF THE INVENTION

It is one of many objects of the present invention to create a lighting device, that has a high functional diversity, which can be used in a flexible fashion and makes a high-quality optical impression. Preferably the lighting device should have reliable and simple cover elements for attenuating the light emitted by the light source of the lighting device.

Preferably the cover element should be arranged to automatically detect that the light source emits a beam of visible light. The present invention may hence be directed to an improved lighting device which comprises a light emitting element and a cover element, which cover element is automatically closed in order to protect, cover, and/or hide the light emitting element when the lighting device is not in use, and which cover element is automatically opened to at least partly allow the light beams of the light emitting element to pass when the lighting device is activated.

It has been noted that the solution according to U.S. Pat. No. 4,513,358 does not work for lighting systems based on light emitting diodes (LEDs), since in comparison to light bulbs LEDs generate very little, or even negligible infrared radiation. Thus, another solution may be needed when aiming at hiding the light source for LED-based lighting systems.

Hence according to a first aspect there is provided a lighting device comprising a light emitting diode configured to emit a beam of visible light along a light path, the light emitting diode being switchable between a first light state and a second light state, the light emitting diode being arranged to emit the beam of visible light at a first intensity in the first light state and to emit the beam of visible light at a second intensity in the second light state, wherein the second intensity is higher than the first intensity; and a cover element at least partly arranged in the light path, the cover element being switchable between a first cover state and a second cover state; wherein the cover element comprises a detector arranged to detect a parameter indicative of the light emitting diode being in the second light state; and the cover element being arranged to switch from the first cover state to the second cover state in response to the detector detecting the parameter.

The second intensity may be at least one order of magnitude larger than the first intensity. According to an embodiment the first intensity corresponds to no light being emitted.

The term “beam of visible light” may relate to a beam of light containing visible light and substantially no infrared radiation. The term “substantially no infrared radiation” should in this context refer to a light emitting element emitting visible light, in contrast to light emitting elements emitting infrared light and no visible light. Thus the term “substantially no infrared radiation” should here be interpreted as a light emitting element which emits very little or even negligible direct infrared radiation. However, indirectly there may still be infrared light generated due to the heat that is generated in the light emitting element. However, this is different from inter alia incandescent light bulbs, since such light bulbs emit both infrared and visible light from its filament, due to which there is much more infrared radiation available.

Thus the cover element may be arranged to switch from the first cover state to the second cover state in response to the detector detecting an intensity increase of the beam of visible light from the first intensity to the second intensity.

The first cover state is different from the second cover state. Furthermore, the first cover state may be a first optical state, the second cover state may be a second optical state. According to an embodiment the first cover state may be a first optical state, wherein the cover element is arranged to be closed, and wherein the cover element is arranged not to allow the emitted beam of visible light to at least partly pass through the cover element; the second cover state may be a second optical state, wherein the cover element is arranged to be open, and wherein the cover element is arranged to allow the emitted beam of visible light to at least partly pass through the cover element and thereby to be emitted out of the lighting device. That is, the cover element may be arranged to be closed in the first cover state and to be open in the second cover state.

According to an embodiment the first cover state may be a first mechanical state, wherein the cover element is arranged to be closed, and wherein the cover element is arranged not to allow the emitted beam of visible light to at least partly be emitted out of the lighting device; the second cover state may be a second mechanical state, wherein the cover element is arranged to be open, and wherein the cover element is arranged to allow the emitted beam of visible light to at least partly be emitted out of the lighting device.

A purpose of the cover element may be to at least partly protect the light emitting diode. A purpose of the cover element may be to at least partly protect the light emitting diode, particularly when the light emitting diode is in the first light state.

A purpose of the cover element may be to at least partly block light, which is emitted by the light emitting diode, to be emitted from the lighting device. Thus the cover element may be arranged to be fully closed in the first cover state. However, it may also be possible that the cover element is at least partly open also in the first cover state. Hence the cover element may be at least partly open allowing light at a first intensity level to be emitted in the first cover state and the cover element may be at least partly open allowing light at a second intensity level to be emitted in the second cover state, wherein the second intensity level is higher than the first intensity level. However, for simplicity and without losing generality, the cover element is said to be closed in the first cover state and open in the second cover state throughout the disclosure.

According to an embodiment the first light state may be associated with the first optical and/or mechanical state; the second light state may be associated with the second optical and/or mechanical state.

The parameter may pertain to at least one property from the group of light flux emitted by the light emitting diode, a temperature change of a heat-sink of the light emitting diode, and the light emitting diode itself.

The light emitting diode may comprise a heat-sink. The parameter may pertain to a temperature change of the heat-sink. The detector may be operatively connected to the heat-sink. Thus an advantage may be that the need of electronics required for the lighting may be reduced. The temperature change is automatically achieved when the lighting device is switched on.

The parameter may pertain to light flux emitted by the light emitting diode. The detector may comprise a photo sensor arranged to detect the light flux. Thus an advantage may be that the cover element may only respond to the light emitting diode when light is generated and not when there is a problem or malfunction in the light source which problem or malfunction generates heat but not light.

The detector may be integrated with the cover element. Thus an advantage may be that a bi-metal may be heated by the heat-sink, and thereby causing the state of the cover element to switch.

The light emitting diode may comprise a light emitting diode package. The cover element may be attached to, or part of, the light emitting diode package. The cover element may thus be attached to the light emitting element. The light emitting diode (LED) package refers to the structure surrounding the LED die. A LED typically comprises a LED die, surrounded and mounted onto the LED package. The LED package and LED die may be delivered as a single product. Thus an advantage may be that the cover element may be integrated with the light emitting diode. The LED package, LED die and cover element may be delivered as a single product. A further advantage may be that the cover element may be located as close as possible to the source of the light (i.e. the light emitting diode). The cover element may be smaller (and cheaper to manufacture) in comparison to a separate cover element. The integrated cover element may respond faster to the parameter in comparison to a separate cover element.

The cover elements may be arranged to collimate the emitted beam of visible light. Thus an advantage may be that the beam may be collimated when the intensity of the emitted light increases. Thus, when more light is desired or needed, the provided collimated beam may further help to increase light intensity. Similarly, when the light intensity is low, the lighting may be less collimated and may provide a more decorative function.

The cover element may comprise a mechanical element arranged to switch the cover element from the first cover state to the second cover state. The mechanical element may comprise at least one shutter. Thus an advantage may be that a mechanical element may operate well with temperature changes.

The at least one shutter may be arranged to form a funnel arranged to collimate the emitted beam of visible light.

The cover element may comprise optical elements arranged to switch the cover element from the first cover state to the second cover state. Thus an advantage may be that optical elements may achieve lighting effects without mechanical movement. Thus, the lighting device may be more or less hidden even when the lighting device is in the second light state.

The optical elements may be arranged to switch between at least two scattering states arranged to collimate the emitted beam of visible light in the second cover state.

The optical elements may further be arranged to form a lens arranged to collimate the emitted beam of visible light.

The mechanical element may comprise a reflector, wherein the reflector is one from a thermo-chromic reflector and a photo-chromic reflector. The reflector may be arranged to change at least one of the color and the polarization of the emitted light beam when the emitted light beam is reflected on the reflector.

The optical elements may comprise phosphor particles. The phosphor particles may be arranged to change at least one of the color and the polarization of the emitted light beam when the emitted light beam passes through the optical elements. Thus an advantage may be that the color of the lighting system may change depending on light output.

The detector may be arranged to detect a parameter indicative of the light emitting diode switching from the second light state to the first light state; and the cover element may be arranged to switch from the second cover state to the first cover state in response to the detector detecting the parameter. That is, the detector may be arranged to also detect the light emitting diode being switched off Thus an advantage may be that when the light emitting diode is no longer switched on it may be protected by the cover element. An advantage may be that when the light emitting diode is no longer switched on it may be hidden by the cover element.

According to a second aspect there is provided a luminaire comprising a lighting device according to the above.

According to a third aspect there is provided a method in a lighting device, the lighting device comprising a light emitting diode configured to emit a beam of visible light along a light path, the light emitting diode being switchable between a first light state and a second light state, the light emitting diode being arranged to emit the beam of visible light at a first intensity in the first light state and to emit the beam of visible light at a second intensity in the second light state, wherein the second intensity is higher than the first intensity, and a cover element at least partly arranged in the light path, the cover element being switchable between a first cover state and a second cover state, the method comprising switching the light emitting diode from the first light state to the second light state; emitting the beam of visible light by the light emitting diode at the second intensity; detecting a parameter by a detector of the cover element, wherein the parameter is indicative of the light emitting diode being in the second light state; and switching the cover element from the first cover state to the second cover state in response to the detected parameter.

The method may further comprise detecting the parameter from a heat-sink of the light emitting diode. The parameter may pertain to a temperature change of the heat-sink.

The method may further comprise detecting the parameter from light emitted by the light emitting diode. The parameter may pertain to a flux change of the emitted beam of visible light.

There is provided a cover element adapted to be arranged in a light path of a light emitting element; wherein the cover element comprises a detector arranged to detect a parameter of the light emitting element; a switch arranged to switch the cover element between a first cover state and a second cover state, wherein the switch is arranged to switch the cover element from the first cover state to the second cover state in response to the detector detecting the parameter.

The cover element may be arranged to be closed in the first cover state and to be open in the second cover state.

The parameter may pertain to at least one property from the group of light flux emitted by the light emitting diode, a temperature change of a heat-sink of the light emitting diode, and the light emitting diode itself.

The lighting devices described above with references to the first, second, and third aspects thus enable automatic operation of the cover elements without complicated circuitry or switching, they may provide excellent protection for the light emitting diode when the cover element is closed, and they even provide some degree of protection against impact of objects against the light emitting diode when the cover element is open. Further, the cover element may respond to visible light. The cover element may respond to the temperature of a heat-sink connected to the light emitting diode. Generally, the second and third aspects have the same advantages as the first aspect.

These and other aspect of the invention will be apparent from and elucidated with reference to the embodiments described hereinafter.

Generally, all terms used in the claims are to be interpreted according to their ordinary meaning in the technical field, unless explicitly defined otherwise herein. All references to “a/an/the/said [element, device, component, means, step, etc]” are to be interpreted openly as referring to at least one instance of said element, device, component, means, step, etc., unless explicitly stated otherwise. The steps of any method disclosed herein do not have to be performed in the exact order disclosed, unless explicitly stated.

### BRIEF DESCRIPTION OF THE DRAWINGS

Other features and advantages of the present invention will become apparent from the following detailed description of a presently preferred embodiment, with reference to the accompanying drawings, in which:

FIGS. 1a-1f illustrate light emitting elements according to embodiments of the invention;

FIGS. 2a-2k illustrate lighting devices according to embodiments of the invention;

FIGS. 3a-3b illustrate lighting devices according to embodiments of the invention;

FIGS. 4a-4b show flowcharts for methods according to embodiments of the invention.

### DETAILED DESCRIPTION OF EMBODIMENTS

The present invention will now be described hereinafter with reference to the accompanying drawings, in which certain embodiments of the invention are shown. This invention may, however, be embodied in many different forms and should not be construed as limited to the embodiments set forth herein; rather, these embodiments are provided by way of example so that this disclosure will convey the scope of the invention to those skilled in the art. Like numbers refer to like elements throughout.

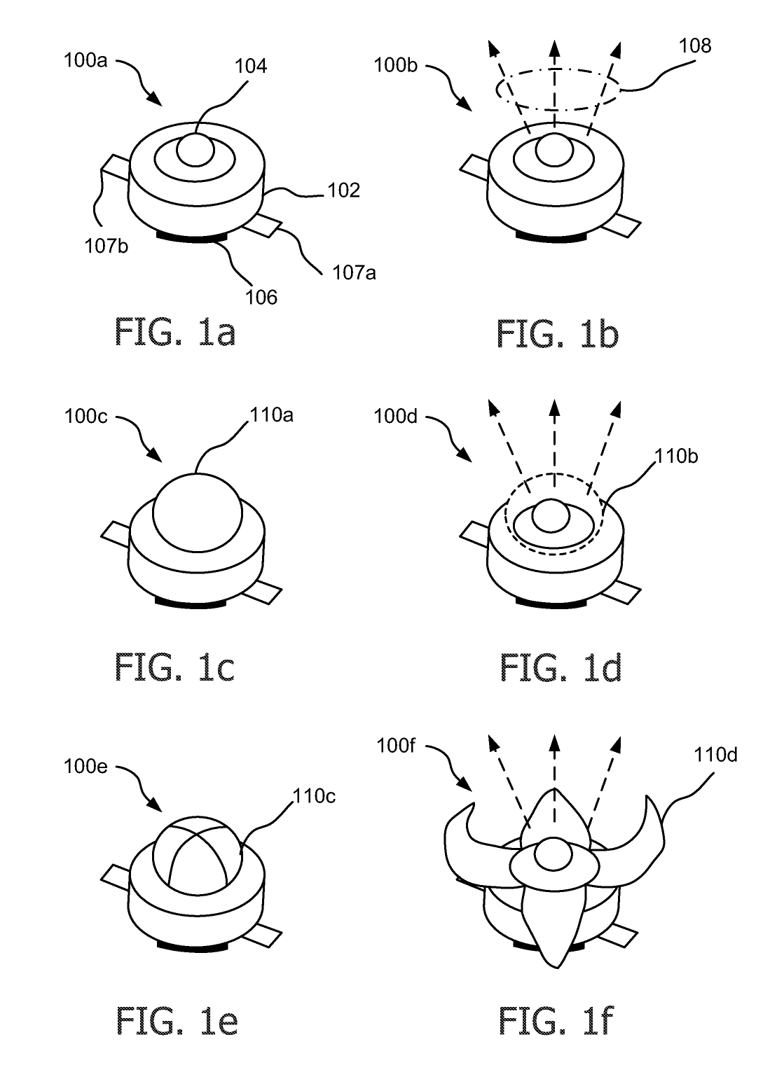

FIG. 1a illustrates a light emitting element 100a according to an embodiment. The light emitting element 100a comprises a body 102 and a light source 104. The body 102 may be arranged to provide means for arranging the light emitting element 100a in a lighting device. The light emitting element further comprises a heat-sink 106. The light emitting element may further comprise one or more electrical contacts 107a, 107b. The light emitting element 100a is switchable between a first light state and a second light state, wherein the light emitting element is arranged to emit a beam of visible light at a first intensity in the first light state and to emit the beam of visible light at a second intensity in the second light state, wherein the second intensity is higher than the first intensity. The second intensity may be at least one order of magnitude larger than said first intensity. The first intensity may correspond to no light being emitted.

The light emitting element 100a may be a solid-state light source. The light emitting element 100a may be a light emitting diode (LED), an organic LED (OLED) or a polymer (polyLED). Solid-state light sources, such as LEDs OLEDs or polyLEDs, may offer several advantages over traditional light sources, such as light bulbs. One advantage may be long lifetime. One advantage may be low operating voltage. One advantage may be small form factor (thereby providing design flexibility). One advantage may be that solid-state light sources may emit almost pure spectral colors. One advantage may be fast modulation of lumen output. One advantage may be a rapid switch between the first light state and the second light state. One advantage may be less radiated infrared or UV light. Lighting devices based on LEDs may provide the designer of the lighting device with more freedom to choose, for instance, the shape of the lighting device. Hence, LED based lighting devices may be more convenient when creating light effects, without disturbing the visual appearance of a space in which the lighting device is to be arranged in.

The LED may comprise a LED package. The LED package refers to the structure surrounding the LED die. A LED typically comprises a LED die, surrounded and mounted onto a LED package.

FIG. 1b illustrates a light emitting element 100b similar to the light emitting element 100a of FIG. 1a according to an embodiment. In the illustrative example of FIG. 1b the light emitting element is in the second light state and thus emits a beam of visible light at a second intensity as illustrated by the arrows associated with the reference numeral 108, wherein the arrows may represent a light path and the ellipse 108 may represent a beam of light. Thus in this figure and all subsequent figures a light emitting element illustratively being associated with the second light state is illustrated with arrows indicating the emitted beam of visible light at the second intensity of the light emitting element.

FIG. 1c illustrates a light emitting element 100c similar to the light emitting elements 100a of FIG. 1a and 100b of FIG. 1b according to an embodiment. In the illustrative example of FIG. 1c the light emitting element 100c is in the first light state. The light emitting element 100c further comprises a cover element 110a. According to an embodiment the cover element 110a may fully cover the light source 100a. In other words, according to an embodiment the cover element may be fully arranged in the light path of the light source.

The cover element 110a is switchable between a first cover state and a second cover state, wherein the cover element is arranged to be closed in the first cover state and to be open in the second light state. The cover element comprises a detector arranged to detect a parameter indicative of the light source of the light emitting element switching from the first light state to the second light state, and from the second light state to the first light state. The cover element is arranged to switch from the first cover state to the second cover state in response to the detector detecting the parameter. Thus when the light source 104 is switched from the first light state to the second light state the cover element 110a switches from the first cover state to the second cover state, wherein the cover element is at least partly transparent in the second cover state in order to let the emitted light beam at the second intensity pass through. The cover element may inter alia be of a scattering liquid crystal (LC) layer that is arranged to undergo a phase transition to a transparent isotropic phase, induced from detecting the parameter of the light emitting element 104. Thus the cover element 110a may comprise optical elements arranged to switch the cover element 110a from the first cover state to the second cover state. The cover element may be partly transparent in order to produce diffuse light at low intensities. The cover element may be partly transparent in order to produce directed light at high intensities.

FIG. 1d illustrates a light emitting element 100d similar to the light emitting elements 100a-100c of FIGS. 1a-1c according to an embodiment. In the illustrative example of FIG. 1d the light emitting element 100d is in the second light state. The light emitting element 100d further comprises a cover element 110b similar to the cover element 110a of FIG. 1c. The cover element 110b thus covers the light source 104. In the illustrative example of FIG. 1d the cover element 110b is in the second cover state, as indicated by being illustrated with dashed lines, thereby allowing the light beam at the second intensity emitted by the light source 104 to at least partly pass through the cover element 110b as indicated by the dashed arrows.

FIG. 1e illustrates a light emitting element 100e similar to the light emitting elements 100a-100d of FIGS. 1a-1d according to an embodiment. In the illustrative example of FIG. 1e the light emitting element 100e is in the first light state. The light emitting element 100e further comprises a cover element 110c. The cover element 110c thus covers the light source 104. In the illustrative example of FIG. 1e the cover element 110c is in the first cover state. The cover element 110c may comprise a mechanical element arranged to switch the cover element 110c between the first cover state and the second cover state. The mechanical element may further comprise at least one shutter. For example, an opaque thin bilayer or shape-memory material may cover the light source in the first cover state. When the light source is switched from the first light state to the second light state, the thin bilayer may be arranged to curl away from the light source, which opens up the shutter.

FIG. 1f illustrates a light emitting element 100f similar to the light emitting elements 100a-100e of FIGS. 1a-1e according to an embodiment. In the illustrative example of FIG. 1f the light emitting element 100f is in the second light state. Further, the cover element 110d, similar to the cover element 110c of FIG. 1e is in the second cover state. Thus the cover element 110d is arranged to at least partly allow the light beams at the second intensity of the light source 104 to be emitted, as indicated by the illustrative dashed arrows.

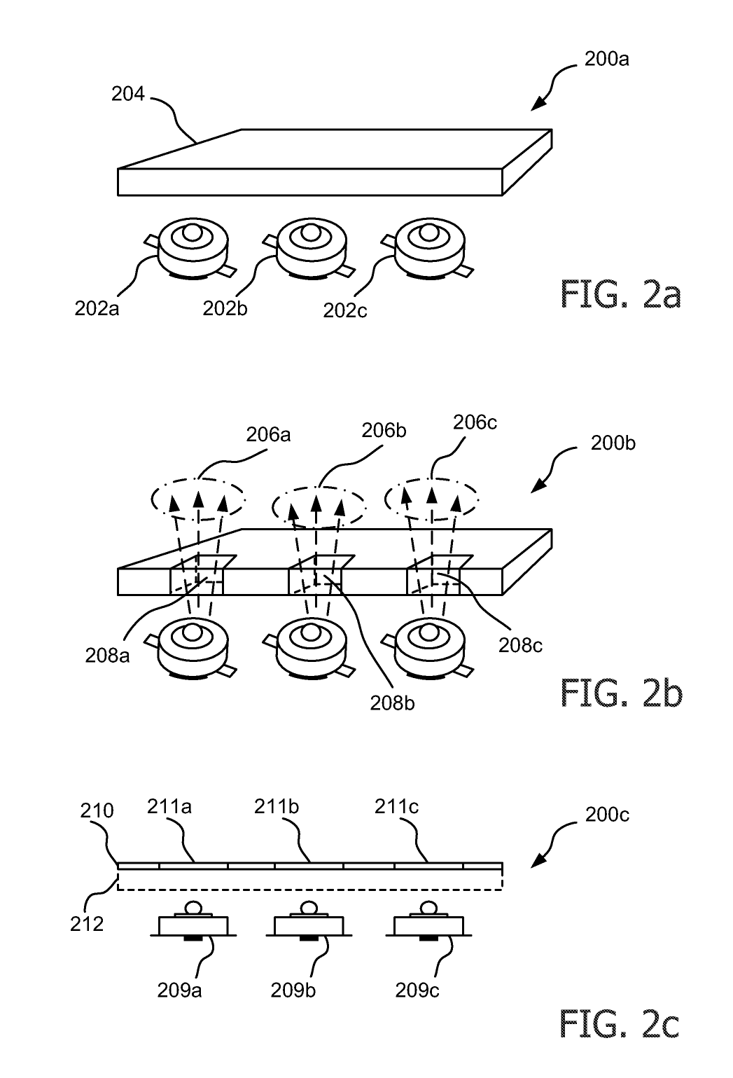

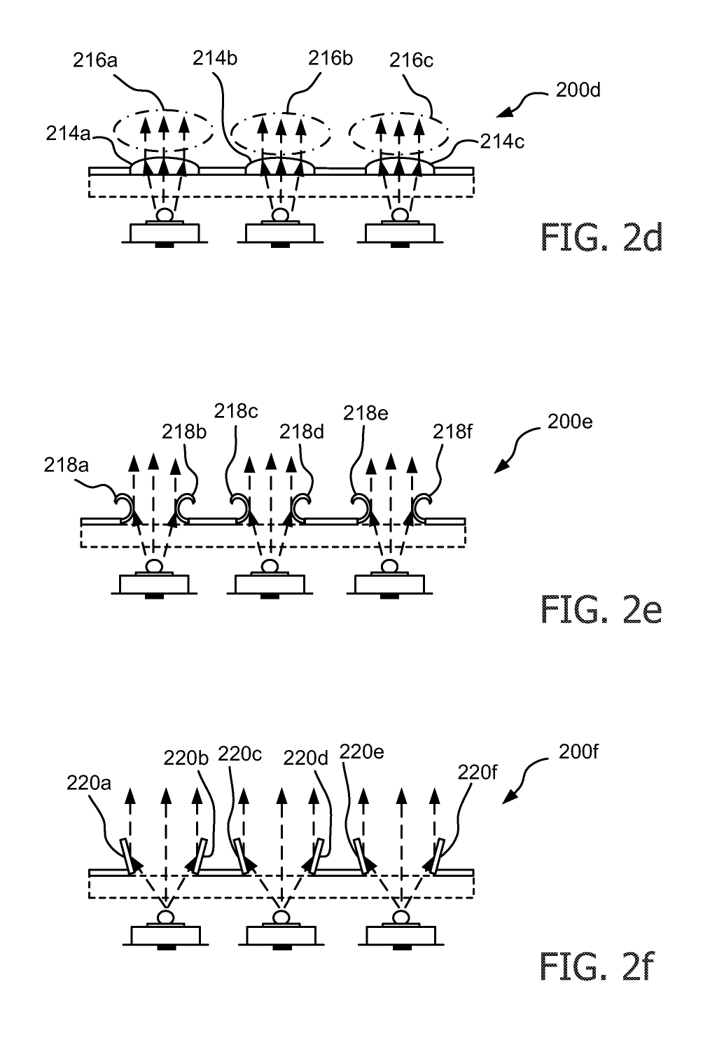

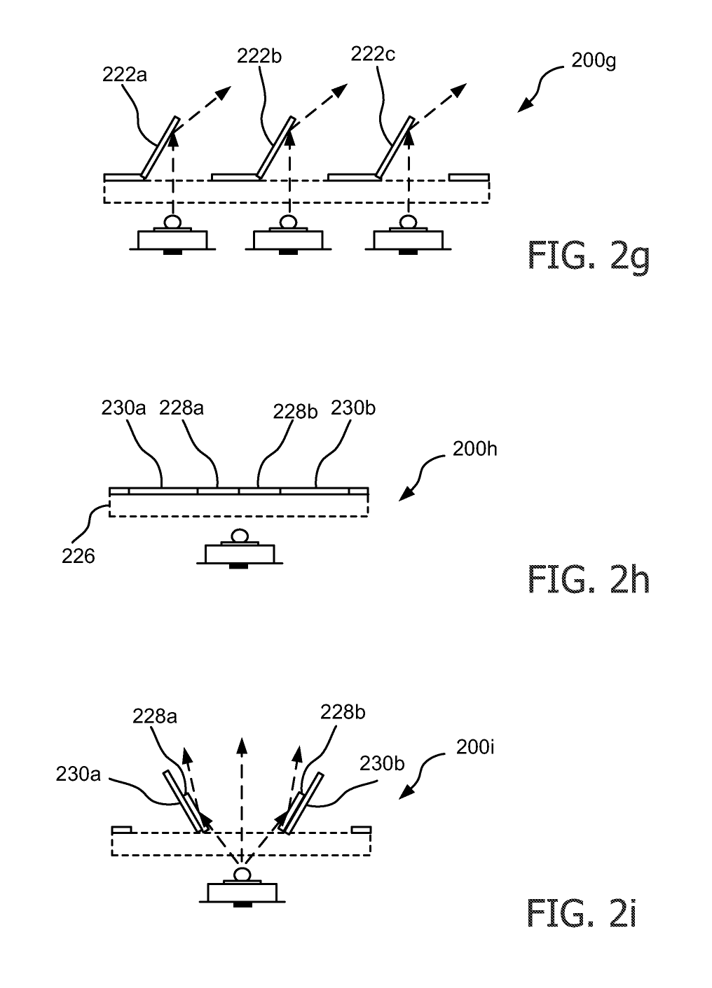

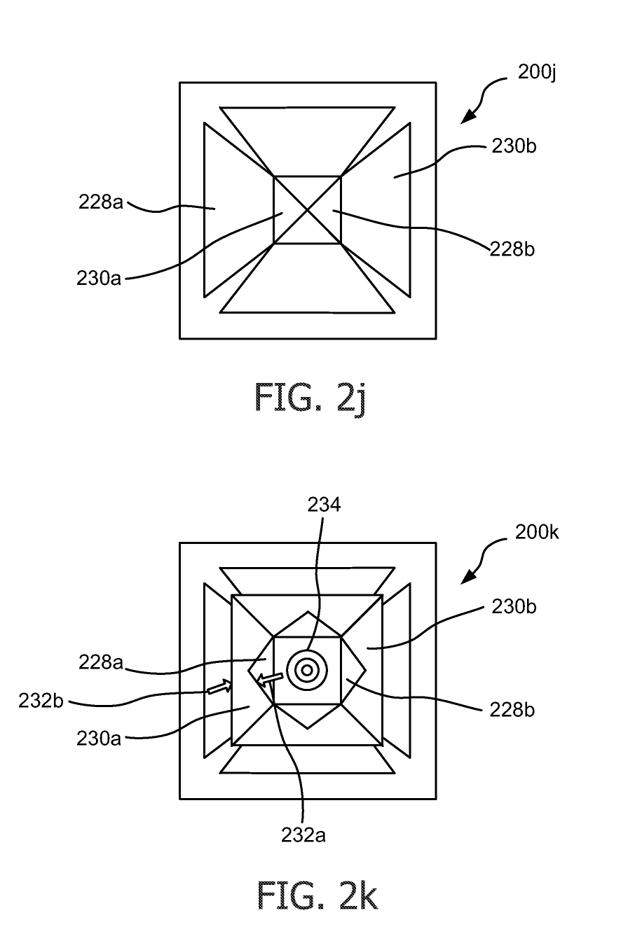

FIG. 2a illustrates a lighting device 200a according to an embodiment. An example of a lighting device is a device that is used for providing light in an area, for purpose of illuminating objects in the area by emitting one or more beams of light. An area should in this context be interpreted broadly. An area is in this context typically an apartment room or an office room, a gym hall, a room in a public place or a part of an outdoor environment, such as a part of a street. The lighting device 200a comprises one or more light emitting elements 202a, 202b, 202c such as one or more of the light emitting elements 100a and 100b of FIG. 1a and FIG. 1b as disclosed above. Alternatively, one or more of the light emitting elements 202a, 202b, 202c may be similar to the light emitting elements 100c-100f as disclosed above with references to FIGS. 1c-1f. The lighting device 200a further comprises a common cover element 204. The common cover element 204 may be a cover element similar to the cover elements 110a-110d of FIGS. 1c-1f. In FIG. 2a one common cover element 204 is arranged to simultaneously cover all light emitting elements 202a-202c. In contrast, in FIGS. 1c-1d the individual cover elements 110a-110d are associated with individual light emitting elements. However, the individual cover elements and the common cover elements may serve similar purposes.

In the lighting devices 200b of FIG. 2b light emitting elements, such as the light emitting elements 202a-c are placed behind the common cover element. According to an embodiment the cover element 204 may thus at least partly cover the light source 202a-202c. The common cover element may comprise one or more light scattering elements. When the light emitting elements are switched from the first light state to the second light state, the scattering elements are arranged to switch to a transparent mode, as illustrated by the optical elements indicated by the reference numerals 208a, 208b, 208c, in order to let the light beams at the second intensity of the light emitting elements pass through, as illustrated by arrows 206a, 206b, 206c representing the emitted beams of light. For example, the scattering element may comprise one or more scattering LC layers that undergo a phase transition to a at least partly transparent isotropic phase. Similar to the cover elements 110a and 110b of FIGS. 1c-1d, in the second cover state the scattering element may be partly transparent in order to produce diffuse light at low intensities and/or directed light at high intensities. Instead of scattering, the cover element may also be opaque and switchable to a transparent state when the light sources are switched on. For example, a switchable diffuser with dispersed pigments may be used: in the transparent state, the path length of a light ray in the pigmented layer may be shorter than in the diffuse state. Hence the absorption of the light may be much lower in the transparent state than in the diffuse state.

FIG. 2c is a side view of a lighting device 200c, similar to the lighting devices 200a and 200b of FIG. 1a and FIG. 1b. The lighting device 200c comprises one or more light emitting elements 209a, 209b, 209c such as the light emitting elements 202a-202c of FIG. 2a and a common cover element 210. The common cover element 210 may be associated with one or more individual cover elements 211a, 211b, 211c. The common cover element may support the individual cover elements. The number of individual cover elements may be identical to the number of light emitting elements. The common cover element 210 may be attached to a plate, as illustrated by the reference numeral 212 in FIG. 2c. The individual cover elements 211a-211c may be attached to the plate 212. The plate 212 may be of an at least partly transparent material.

The common and/or individual cover elements may be arranged to form a lens when switched from the first cover state to the second cover state. FIG. 2d illustrates a lighting device 200d comprising individual cover elements 214a, 214b, 214c which are arranged in the second cover state. As illustrated in FIG. 2d the cover elements 214a-214c have swelled such that a lens is formed. The cover elements may be arranged to change shape and/or form when detecting a parameter of the one or more light emitting elements. Thus the one or more lenses may be arranged to be automatically aligned with the light emitting elements. Depending on the material and/or shape of the one or more lenses the one or more lenses may thus enable scattering or collimation of the emitted light beams as indicated by the arrows 216a, 216b, 216b in FIG. 2d. The common and/or individual cover elements may be made from shape memory polymers, such as poly-urethane based materials. Other options may be to use electrowetting lenses or liquid crystal lenses that are switchable between the first cover state and the second cover state depending on the light flux of the light emitting element via an electrode that can be charged or de-charged via a photocurrent.

The common cover element may also comprise one or more mechanical cover elements. The cover element of the lighting device 200e of FIG. 2e comprises mechanical cover elements 218a, 218b, 218c, 218d, 218e, 218f. In the lighting device 200e of FIG. 2e the cover elements 218a-218f are arranged to, when switched from the first cover state to the second cover state, curl away from the light source and thereby to enable light beams to be emitted. In FIG. 2e the emitted light beams are illustrated by arrows. Depending on inter alia the shape of the curled elements the curled elements may be utilized to collimate or shape the beam of the emitted light as indicated by the arrows depicted in FIG. 2e.

The effects used for switching a beam shutter may also be applied for beam shaping (collimation) or beam steering. For example, a switchable diffuser may be switchable between different scattering states in order to produce beams of different widths. The light beam may also be collimated by a mechanical shutter that forms a reflective funnel in the open state. FIG. 2f illustrates a lighting device 200f comprising mechanical shutters 220a, 220b, 220c, 220d, 220f. The mechanical means shutters 220a-220f may be arranged to pivot between a closed state associated with the first cover state and an open state associated with the second cover state. In the open state the mechanical shutters 220a-220f may thereby enable a reflective light funnel to be formed. The side of the shutters 220a-220f receiving the emitted beam of visible light at the second intensity may be reflective in order to shape the beam (with the collimating funnel).

An asymmetric funnel may be used to steer the emitted beam of visible light at the second intensity in a given direction. FIG. 2g illustrates a lighting device 200g comprising mechanical shutters 222a, 222b, 222c. The mechanical shutters 222a-222c may be arranged to pivot between a closed state associated with the first cover state and an open state associated with the second cover state. In the second cover state the mechanical shutters 222a-222c may thereby enable to steer the emitted beam of visible light at the second intensity in a given direction. The side of the shutters 222a-222f receiving the emitted beam of visible light may be reflective in order to direct the beam with an asymmetric reflector. FIG. 2h and FIG. 2i illustrate a further example of lighting devices 200h, 200i comprising mechanical shutters 228a, 228b, 230a, 230a. The mechanical shutters 228a, 228b, 230a, 230a may be arranged to pivot between a closed state associated with the first cover state, as in FIG. 2h, and an open state associated with the second cover state, as in FIG. 2i. FIG. 2h illustrates a closed collimator formed by reflective inner shutters, or flaps, 228a, 228b and reflective outer shutters, or flaps, 230a, 230b that are arranged to be folded out when the light source is operating. FIG. 2i illustrates an open collimator.

FIG. 2j is a top view of a lighting device 200j similar to the lighting devices 200h and 200i comprising mechanical shutters 228a, 228b, 230a, 230a in the first cover state.

FIG. 2k is a top view of a lighting device 200k similar to the lighting devices 200h, 200i comprising mechanical means shutters 228a, 228b, 230a, 230a in the second cover state as illustrated by the arrows 232a and 232b, thereby making a light emitting element 234 visible.

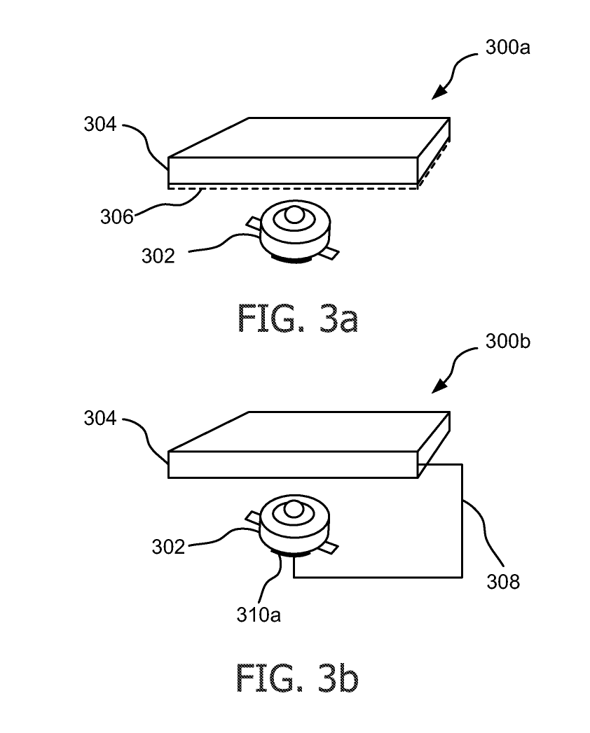

The individual and/or common cover elements may comprise a detector arranged to detect a parameter indicative of the light emitting element switching from the first light state to the second light state. The detector may comprise a photo sensor. The detector may be arranged to be connected to a heat-sink of the light emitting element. The lighting device such as the lighting devices 200a-200k of FIGS. 2a-2k may thus comprise a photo sensor. FIG. 3a illustrates a lighting device 300a similar to the lighting devices 200a-200k of FIGS. 2a-2k. The lighting device 300a comprises one or more light emitting elements 302 and a cover element 304. The lighting device 300a further comprises a photo sensor, schematically illustrated by the reference numeral 306. The photo sensor 306 may be arranged to detect light flux emitted by the light emitting element 302. The photo sensor 306 may be operatively connected to the cover element 304. Upon detecting a parameter, such as light flux, the photo sensor may be arranged to transmit an indication to the cover element to switch from the first cover state to the second cover state. Alternatively the photo sensor may be arranged to transmit an indication pertaining to the light emitting element switching between the first light state and the second light state to the cover element. The switching of the cover element may thus be induced by the light flux emanating from the light source. Photo sensors are here to be interpreted broadly as sensors capable of detecting light. Photo sensors as such are known in the art and will therefore not be elaborated on further in this disclosure.

The lighting device such as the lighting devices 200a-200i of FIGS. 2a-2i may comprise a heat-sink. FIG. 3b illustrates a lighting device 300b similar to the lighting devices 200a-200i and 300a of FIGS. 2a-2i and 3a. The lighting device 300b comprises one or more light emitting elements 302 and a cover element 304. The lighting device 300b further comprises a heat-sink, schematically illustrated by the reference numeral 310a. The parameter detected by the detector may thus pertain to a temperature change of the heat-sink. The detector may be operatively connected to the heat-sink, as illustratively indicated by the connection 308. The detector may detect heating of the heat-sink by being in thermal contact with the heat-sink. Thus there may be a connection between the cover element and the heat-sink, such that the cover element is heated when the light source is switched off, due to which a change of state for the cover element is induced automatically. The detector and the cover element may be integrated. The cover element may further be heated through contact with the heat-sink, due to which the cover element changes in state. The cover element may change in state due to a bi-metal that changes shape with temperature.

Similar to light beam direction and light beam collimation, also the color and/or the polarization of the light beam may be altered by elements that are switched depending on a parameter. For example, a cover element comprising a switchable diffuser may be mixed with phosphor particles. The color conversion by the phosphor may then be tuned by varying the diffusiveness (and hence the optical path length inside the phosphor layer) of the cover element.

This effect is similar to the switchable shutter based on a switchable diffuser mixed with pigments as disclosed above with reference to FIG. 2b. The variable color conversion by the phosphor may be linked to the temperature of the light emitting element. The color may be variable in such a way as to compensate and/or diminish the light emitting element's color point variations with temperature.

The cover element may comprise a thermo-chromic or photo-chromic reflector. The light beam may thus be reflected by a thermo-chromic or photo-chromic reflector. Induced by the heat or irradiation of the light emitting element, the color of the reflector may change. Hence the color of the reflected light beam may also change. Also the cover elements comprising mechanically moveable shutters may be used to vary color and/or polarization. The shutters may not be opaque or reflective, but (partially) transparent. The cover elements may inter alia comprise at least one from the group of (reflective) color filters, phosphor layers, (reflective) polarisers, or any combinations of these. The switching of the cover element may thus also be used to change the color of the light and/or the polarization.

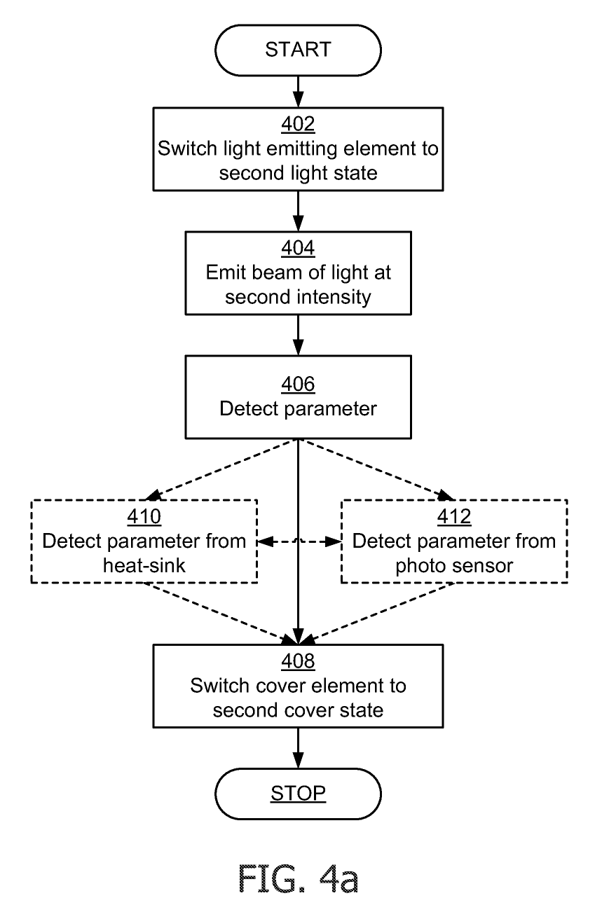

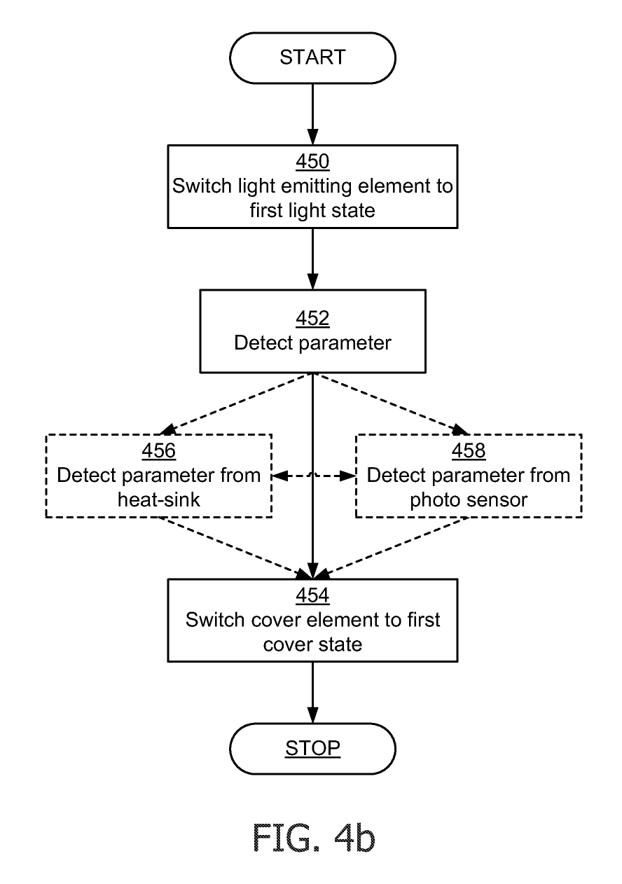

FIG. 4a shows a flowchart for a method in a lighting device such as the above disclosed lighting devices. The lighting device comprises a light emitting element, such as the above disclosed light emitting devices, arranged to emit a beam of visible light along a light path and a cover element, such as the above disclosed cover elements arranged in the light path. The light emitting element is switchable between a first light state and a second light state, wherein the light emitting element is arranged to emit the beam of visible light at a first intensity in the first light state and to emit the beam of visible light at the second intensity in the second light state. The cover element is switchable between a first cover state and a second cover state.

The method comprises switching, in a step 402, the light emitting element from the first light state to the second light state. The light emitting element may be arranged to be automatically or manually switched from the first light state to the second light state. The light emitting element may be arranged to be automatically switched when receiving a light controlling signal inter alia from an external control signal operatively connected to a sensor.

When switched to the second light state the light emitting element is arranged to emit a beam of visible light at a second intensity. The method thus further comprises emitting, in a step 404, the beam of visible light at the second intensity by the light emitting element.

When the light emitting element has been switched to the second light state the cover element should allow at least part of the light beams to pass. The cover element may therefore be operatively connected to a detector which is arranged to detect a parameter associated with the light emitting element switching between the first light state and the second light state. The cover element is at least partly arranged in the light path. The method thus further comprises detecting, in a step 406, a parameter by a detector of the cover element. The parameter is indicative of the light emitting element switching from the first light state to the second light state.

When the light parameter has been detected the cover element automatically switches from the first cover state to the second cover state. That is, the cover element may switch from being closed to being open. The method thus further comprises switching, in a step 408, the cover element from the first cover state to the second cover state in response to the detected light parameter.

The light emitting element may comprise a heat-sink. Thus the method may further comprise detecting, in a step 410, the parameter from a heat-sink of the light emitting element. The heat-sink may increase in temperature as a result of the light emitting element being switched from the first light state to the second light state. The parameter may thus pertain to a temperature change of the heat-sink.

The light emitting element may comprise a photo sensor. Thus the method may further comprise detecting, in a step 412, the light parameter from light emitted by the light emitting element. The emitted beam of visible light is associated with a light flux. The light parameter may thus pertain to a flux change of the emitted beam of visible light.

FIG. 4b shows a flowchart for a method in a lighting device such as the above disclosed lighting devices. The lighting device comprises a light emitting element, such as the above disclosed light emitting devices, arranged to emit a beam of visible light along a light path and a cover element, such as the above disclosed cover elements arranged in the light path.

The method comprises switching, in a step 450, the light emitting element from the second light state to the first light state. The light emitting element may be arranged to be automatically or manually switched from the second light state to the first light state. The light emitting element may be arranged to be automatically switched when receiving a light controlling signal inter alia from an external control signal operatively connected to a sensor.

When the light emitting element has been switched to the first light state the cover element should cover the light emitting element. The cover element may therefore be operatively connected to a detector which is arranged to detect a parameter associated with the light emitting element switching between the first light state and the second light state. The method further comprises detecting, in a step 452, a parameter by a detector of the cover element. The parameter is indicative of the light emitting element switching from the second light state to the first light state.

When the light parameter has been detected the cover element automatically switches from the second cover state to the first cover state. The method thus further comprises switching, in a step 454, the cover element from the second cover state to the first cover state in response to the detected parameter.

The light emitting element may comprise a heat-sink. Thus the method may further comprise detecting, in a step 456, the parameter from a heat-sink of the light emitting element. The heat-sink may decrease in temperature as a result of the light emitting element being switched from the second light state to the first light state. The light parameter may thus pertain to a temperature change of the heat-sink.

The light emitting element may comprise a photo sensor. Thus the method may further comprise detecting, in a step 458, the light parameter from light emitted by the light emitting element. The emitted beam of visible light is associated with a light flux. As the light emitting element is switched from the second light state to the first light state the associated beam of visible light is also switched from emitting a beam of light at second intensity to the first intensity. The parameter may thus pertain to a flux change of the emitted beam of visible light.

The invention has mainly been described above with reference to a few embodiments. However, as is readily appreciated by a person skilled in the art, other embodiments than the ones disclosed above are equally possible within the scope of the invention, as defined by the appended patent claims.

1. A lighting device comprising:
a light emitting diode configured to emit a beam of visible light along a light path, said light emitting diode being switchable between a first light state and a second light state, said light emitting diode being arranged to emit said beam of visible light at a first intensity in said first light state and to emit said beam of visible light at a second intensity in said second light state, wherein said second intensity is higher than said first intensity; and
a cover element at least partly arranged in said light path, said cover element being switchable between a first cover state and a second cover state and comprising a detector arranged to detect a parameter indicative of said light emitting diode being in the second light state; said cover element being configured to switch from said first cover state to said second cover state in response to said detector detecting said parameter.

2. The lighting device according to claim 1, wherein
said light emitting diode comprises a heat-sink;
said parameter pertains to a temperature change of said heat-sink; and wherein
said detector is operatively connected to said heat-sink.

3. The lighting device according to claim 1, wherein
said light parameter pertains to light flux emitted by said light emitting diode; and wherein
said detector comprises a photo sensor arranged to detect said light flux.

4. The lighting device according to claim 1, wherein said detector is integrated with said cover element.

5. The lighting device according to claim 1, wherein said light emitting diode comprises a light emitting diode package, and wherein said cover element is attached to said light emitting diode package.

6. The lighting device according to claim 1, wherein said second intensity is at least ten times larger than said first intensity.

7. The lighting device according to claim 1, wherein said cover element is arranged to collimate said emitted beam of visible light.

8. The lighting device according to claim 1, wherein said cover element comprises a mechanical element configured to switch said cover element from said first cover state to said second cover state; and wherein said mechanical element comprises at least one shutter.

9. The lighting device according to claim 8, wherein said mechanical element comprises a reflector, wherein said reflector is one from a thermo-chromic reflector and a photo-chromic reflector; and wherein said reflector is configured to change at least one of the color and the polarization of said emitted light beam when said emitted light beam is reflected on said reflector.

10. The lighting device according to claim 1, wherein said cover element comprises optical elements configured to switch said cover element from said first cover state to said second cover state.

11. The lighting device according to claim 10, wherein said optical elements are further configured to form a lens arranged to collimate said emitted beam of visible light.

12. The lighting device according to claim 1, wherein said optical elements comprise phosphor particles; and wherein said phosphor particles are arranged to change at least one of the color and the polarization of said emitted light beam when said emitted light beam passes through said optical elements.

13. A method for controlling a lighting device, said lighting device comprising a light emitting diode configured to emit a beam of visible light along a light path, said light emitting diode being switchable between a first light state and a second light state, said light emitting diode being arranged to emit said beam of visible light at a first intensity in said first light state and to emit said beam of visible light at a second intensity in said second light state, wherein said second intensity is higher than said first intensity, and a cover element at least partly arranged in said light path, said cover element being switchable between a first cover state and a second cover state, said method comprising:
switching said light emitting diode from said first light state to said second light state;
emitting said beam of visible light by said light emitting diode at said second intensity;
detecting a parameter by a detector of said cover element, wherein said parameter is indicative of said light emitting diode being in said second light state; and
switching said cover element from said first cover state to said second cover state in response to said detected parameter.

14. The method according to claim 13, comprising
detecting said parameter from a heat-sink of said light emitting diode; and wherein
said parameter pertains to a temperature change of said heat-sink.

15. (canceled)
